(19) United States
(12) Patent Application Publication
(10) Pub. No.: US 2025/0346994 A1
(43) Pub. Date: Nov. 13, 2025

(54) Broadband Low-Noise Figure Bismuth-Doped Silica Fiber for O+E Band and Its Fabrication Method

(71) Applicant: Shanghai University, Shanghai (CN)

(72) Inventors: Tingyun Wang, Shanghai (CN); Weiqi Wang, Shanghai (CN); Jianxiang Wen, Shanghai (CN); Yuanyuan Yang, Shanghai (CN); Yanhua Dong, Shanghai (CN)

(21) Appl. No.: 19/196,808

(22) Filed: May 2, 2025

(30) Foreign Application Priority Data
May 7, 2024 (CN) 2024105558681

(51) Int. Cl. C23C 16/40; C23C 16/30; C23C 16/455; G02B 6/036

(52) U.S. Cl. CPC C23C 16/402; C23C 16/305; C23C 16/407; C23C 16/45553; C23C 16/45555; G02B 6/036

(57) ABSTRACT

The present disclosure discloses broadband low-noise figure bismuth-doped silica fiber for the O+E band and its fabrication method. The fiber, from the outside to the inside, successively includes a cladding (1) and a core. The core, from the outside to the inside, successively includes a loose layer (2), an active core layer (3), a loose layer (2), an active core layer (3), and an inner core layer (4). The cladding (1) is made of pure silica material. The loose layer (2) and the inner core layer (4) are formed by depositing a SiO₂ material doped with GeO₂ and P₂05, and the active core layer (3) is deposited with Bi₂O₃ and PbS nanoparticles. According to the above technical solution, the Bi doping concentration and luminous efficiency can be improved, the fiber length can be reduced, the influence of amplified spontaneous emission (ASE) noise during transmission can be reduced.

### CROSS-REFERENCE TO RELATED APPLICATION

This application claims priority from the Chinese patent application 2024105558681 filed May 7, 2024, the content of which is incorporated herein in the entirety by reference.

### TECHNICAL FIELD

The present disclosure relates to the technical fields of optical fiber communication and optical fiber technique. Specifically, it relates to a broadband low-noise figure bismuth-doped silica fiber for the O+E band and its fabrication method.

### BACKGROUND ART

With the development of mobile communication and the Internet, various innovative applications such as 5G/6G, artificial intelligence, intelligent transportation, smart grid, and smart home have been developed and applied to people's daily lives. The capacity demand of optical fiber communication systems has experienced explosive growth. As one of the key devices in the communication link, the noise figure characteristics of optical fiber amplifiers are of great significance to the development of optical communication systems. Currently, the noise figure of relatively mature erbium-doped fiber amplifiers is lower than 4 dB, and the noise figure performance of fiber amplifiers in future communication bands will be further optimized. Bismuth-doped fibers exhibit good gain and noise figure characteristics in the near-infrared band. Especially when Bi is in P and Si matrices, it generates O+E band active centers and can be widely applied in fields such as optical amplifiers and lasers.

However, there is still room for further optimization of the O+E band noise figure of bismuth-doped fiber amplifiers:

Regarding the noise figure of both O and E bands simultaneously: The article “Gain Clamped Bi-Doped Fiber Amplifier with 150 nm Bandwidth for O- and E-Bands” studies the O+E band bismuth-doped fiber amplifier, and its noise figure is 6-7 dB. The article “Ultra-Broadband Bismuth-Doped Fiber Amplifier Covering a 115-nm Bandwidth in the O and E Bands” studies the O+E band bismuth-doped fiber amplifier, with the lowest noise figure in the 0 band being approximately 4.1 dB and that in the E band reaching 4.8 dB.

Regarding the noise figure of a single O and a single E bands: In the 0 band, the article “40 dB gain all fiber bismuth-doped amplifier operating in the O-band” studies the O-band bismuth-doped fiber amplifier, with the lowest noise figure being 5 dB. The article “High gain E-band amplification based on the low loss Bi/P co-doped silica fiber” studies the E-band bismuth-doped fiber amplifier, with the lowest noise figure being 4.6 dB. In the E band, the article “Bi-doped fiber amplifiers in the E+S band with a high gain per unit length” studies the E-band bismuth-doped fiber amplifier, with the noise figure as low as 3.6 dB.

In the 2023 Chinese patent “Optical Fiber with Wide Bandwidth and High Gain in O+E Band and Its Regulation Method” (Application No. 202310290976.6), it is proposed that by using the ALD (Atomic Layer Deposition) combined with the MCVD (Modified Chemical Vapor Deposition) technique, a gain greater than 15 dB can be achieved in the range of 1260-1460 nm. This patent proposes the idea of co-doping to broaden the bandwidth, and the ALD+MCVD process improves the doping materials and doping concentrations of optical fibers to reduce the noise figure of optical fiber amplifiers.

However, in practice, bismuth is a hot topic in O+E band doped optical fibers. Amplifiers built with bismuth-doped fibers have made good progress in terms of gain and bandwidth, but the wideband noise figure of bismuth-doped fiber amplifiers remains relatively high.

### SUMMARY

To solve the above problems, the present application provides an O+E band low-noise figure bismuth-doped silica fiber. The fiber, from the outside to the inside, successively includes a cladding (1) and a core. The core, from the outside to the inside, is successively a loose layer (2), an active core layer (3), a loose layer (2), an active core layer (3), and an inner core layer (4).

The cladding (1) is made of pure silica material. The loose layer (2) and the inner core layer (4) are deposited with a SiO₂ material doped with GeO₂ and P₂O₅, and the active core layer (3) is deposited with Bi₂O₃ and PbS nanoparticles.

The doping concentration of Bi ions is 0.02-0.04 mol %.

Furthermore, the diameter of the cladding (1) is 125±2 μm, the diameter of the core is 8±1 μm, and the refractive index difference between the cladding (1) and the core is 0.004-0.010.

The doping concentrations of the SiO₂ material doped with GeO₂ and P₂O₅ include: the doping molar ratio of GeO₂ to SiO₂ is 0.02-0.5; the doping molar ratio of P₂O₅ to SiO₂ is 0.04-0.8; and the doping molar ratio of GeO₂ to P₂O₅ is 0.3-1.5.

On the other hand, the present disclosure discloses a fabrication method of an O+E band low-noise figure bismuth-doped silica fiber, which includes the fabrication of an optical fiber preform and drawing the optical fiber preform into an optical fiber.

The fabrication of the optical fiber preform includes the following steps: depositing the loose layer (2) and the inner core layer (4) by using the modified chemical vapor deposition technique; and depositing Bi₂O₃ and PbS nanoparticles by using the atomic layer deposition technique to form the active core layer (3).

The specific steps of fabricating the optical fiber preform include:
Step 1: Deposit a SiO₂ material doped with a small amount of GeO₂ and P₂O₅ on the inner wall of a silica tube as a loose layer by using the modified chemical vapor deposition technique, and semi-vitrify it to form the loose layer (2).
Step 2: Dope Bi₂O₃ and PbS nanoparticles by using the atomic layer deposition technique to form the active core layer (3).
Step 3: Execute Step 1 and Step 2 again to form the loose layer (2) and the active core layer (3) once more.
Step 4: Deposit a SiO₂ material doped with a small amount of GeO₂ and P₂O₅ on the doped material by using the modified chemical vapor deposition technique, and regulate the optical fiber waveguide parameters to form the inner core layer (4).

Furthermore, when doping Bi₂O₃ and PbS nanoparticles by using the atomic layer deposition technique, the deposition concentrations of various doped materials and the uniformity within the deposition range can be precisely controlled by adjusting the deposition temperature, the pulse time of the precursor, the vapor pressure, the gas flow rate, and the deposition cycle. When doping Bi₂O₃ by using the atomic layer deposition technique, Bi(tmhd)₃ is used as the precursor, and deionized water or ozone is used as the oxygen source. When doping PbS nanoparticles, Pb(tmhd)₂ is used as the precursor, and H₂S is used as the sulfur source.

Furthermore, when depositing SiO₂ by using the modified chemical vapor deposition technique, the flow rate of SiCl₄ is set to 30-50 sccm; when depositing GeO₂, the flow rate of GeCl₄ is set to 20-40 sccm; and when depositing P₂O₅, the flow rate of POCl₃ is set to 400-800 sccm.

Compared with the prior art, the present disclosure has the following remarkable advantages:
1. The ALD technique is used for bismuth ion deposition. Bi₂O₃ and PbS nanoparticles are generated on the semi-vitrified substrate of the loose layer. The size of the PbS nanoparticles is regulated at the atomic level by ALD. The active centers overlap with Bi₂O₃, which improves the luminous efficiency. Moreover, the co-doping increases the dispersibility of Bi ions and improves the bismuth doping concentration.
2. With the ALD+MCVD deposition process, the loose layer and the active core layer are deposited in a cycle twice to form a package, ensuring the efficient retention of the active materials Bi₂O₃ and PbS during the high-temperature rod-shrinking process of MCVD and improving the bismuth doping concentration.
3. A higher bismuth ion doping concentration, accompanied by high-efficiency photoluminescence, means that the required fiber length can be reduced under a certain gain condition. This reduces the influence of the amplified spontaneous emission (ASE) noise on the noise figure during transmission, and also reduces the influence of factors such as bending loss, transmission loss, and product volume in practical applications, making it easy for industrial production.

### DESCRIPTION OF THE DRAWINGS

FIG. 1 is a schematic diagram of the doping distribution of the Bi and PbS co-doped optical fiber according to an embodiment of the present disclosure.

FIG. 2 is a structural diagram of the Bi and PbS co-doped optical fiber according to an embodiment of the present disclosure.

FIG. 3 is a schematic diagram of the gain and noise figure in the O+E band according to Embodiment 1 of the present disclosure.

FIG. 4 is a schematic diagram of the gain and noise figure in the O+E band according to Embodiment 2 of the present disclosure.

Reference numerals: 1-cladding; 2-loose layer; 3-active core layer; 4-inner core layer.

### EMBODIMENTS

The present disclosure proposes an O+E band wideband low-noise figure bismuth-doped silica fiber, mainly aiming to solve the problem of the relatively high noise figure of O+E band bismuth-doped fiber amplifiers. By increasing the bismuth doping concentration in the optical fiber, reducing the fiber length, and reducing the influence of ASE noise during transmission, the noise figure is reduced, so as to improve the transmission efficiency and increase the practical application value. In the fabrication of this optical fiber, the fabrication method provided by the present disclosure fabricates a high-concentration bismuth-doped optical fiber through co-doping and improving the optical fiber fabrication process, realizing wideband low-noise figure optical amplification in O+E band optical amplifiers with a relatively short fiber length.

The specific implementation manner of the present disclosure will be described in detail below in combination with the drawings in the specification.

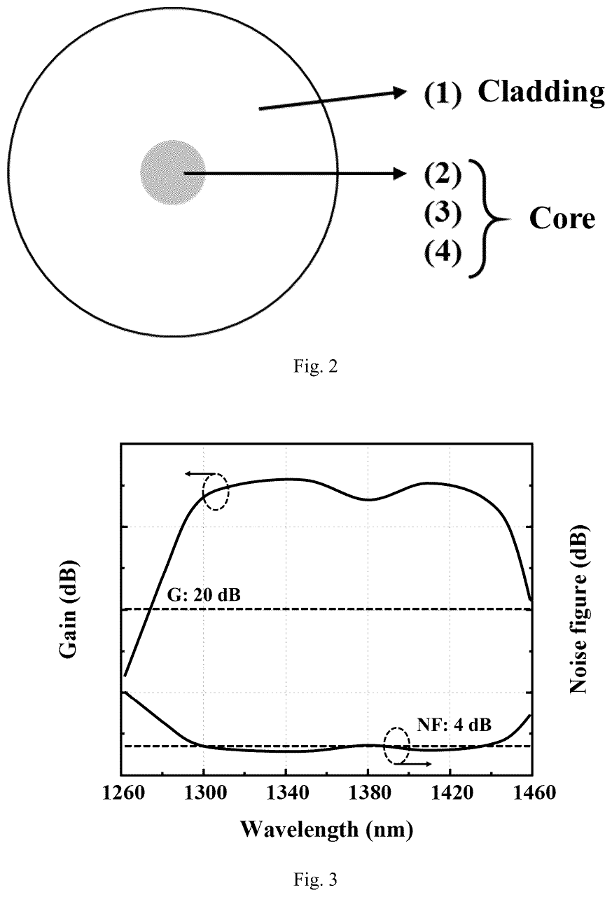

The present disclosure proposes an O+E band low-noise figure bismuth-doped silica fiber. Its structure is shown in FIG. 2. The fiber, from the outside to the inside, successively includes a cladding (1) and a core. The diameter of the cladding (1) is 125±2 μm, and the diameter of the core is 8±1 μm. The refractive index difference between the cladding (1) and the core is 0.004-0.010.

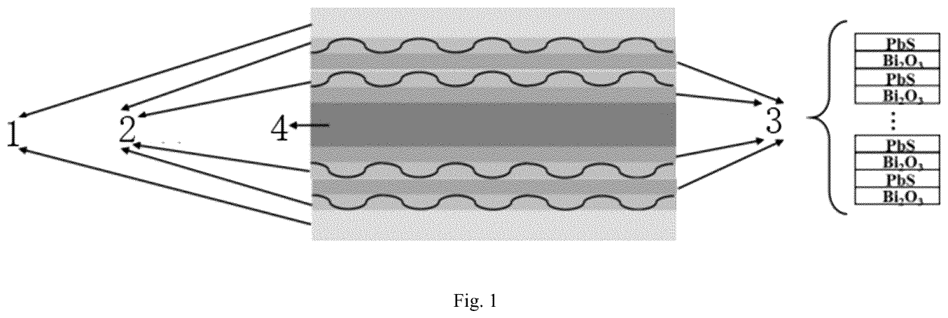

The core includes an outer silica loose layer, a middle active doping layer, and an inner core layer. As shown in FIG. 1, the core, from the outside to the inside, is successively a loose layer (2), an active core layer (3), a loose layer (2), an active core layer (3), and an inner core layer (4).

The cladding (1) is made of pure silica material. The loose layer (2) and the inner core layer (4) are deposited with a SiO₂ material doped with GeO₂ and P₂O₅.

The doping concentrations of the SiO₂ material doped with GeO₂ and P₂O₅ include:
The doping molar ratio of GeO₂ to SiO₂ is 0.02-0.5;
The doping molar ratio of P₂O₅ to SiO₂ is 0.04-0.8;
The doping molar ratio of GeO₂ to P₂O₅ is 0.3-1.5.

The active core layer (3) is deposited with Bi₂O₃ and PbS nanoparticles, and the doping concentration of Bi ions is 0.02-0.04 mol %.

On the other hand, the present disclosure proposes a fabrication method of an O+E band low-noise figure bismuth-doped silica fiber. In the fabrication method, the ALD (Atomic Layer Deposition)+MCVD (Modified Chemical Vapor Deposition) process is used to ensure the uniformity, consistency, and dispersibility of the deposition of Bi₂O₃ and PbS nanoparticles and precisely control the doping concentration.

Specifically, the steps of the fabrication method include the fabrication of an optical fiber preform and drawing the optical fiber preform into an optical fiber.

The fabrication of the optical fiber preform includes depositing the loose layer (2) and the inner core layer (4) by using the MCVD technique; alternately depositing Bi₂O₃ and PbS nanoparticles by using the ALD technique to form the active core layer (3). After the fabrication of the optical fiber preform is completed, the preform is shrunk at a high temperature, and the optical fiber preform is drawn into an optical fiber by using a drawing tower.

Specifically, the specific steps of fabricating the optical fiber preform include:
Step 1: Deposit a SiO₂ material doped with a small amount of GeO₂ and P₂O₅ on the inner wall of a silica tube as a loose layer by using the MCVD technique, and semi-vitrify it to form the loose layer (2). In this step, the MCVD technique is used to construct the loose layer on the silica base tube. The pore characteristics of the loose layer increase the longitudinal surface area for the deposition of active materials. At the same time, the size of the deposited particles can be regulated, the deposition dispersibility is increased, the concentration quenching effect is reduced, and the luminous efficiency is improved. Based on the fact that P doping can reduce the softening temperature, when depositing the loose layer by using the MCVD technique, the doping concentrations are controlled as follows: the doping molar ratio of GeO₂ to SiO₂ is 0.02-0.5; the doping molar ratio of P₂O₅ to SiO₂ is 0.04-0.8; the doping molar ratio of GeO₂ to P₂O₅ is 0.3-1.5. When depositing SiO₂ by using the MCVD technique, the flow rate of SiCl₄ is set to 30-50 sccm; when depositing GeO₂, the flow rate of GeCl₄ is set to 20-40 sccm; when depositing P₂O₅, the flow rate of POCl₃ is set to 400-800 sccm.
Step 2: Dope Bi₂O₃ and PbS nanoparticles by using the ALD technique to form the active core layer (3). In this step, based on the atomic-level regulation of ALD, the size of the PbS nanoparticles can be effectively controlled, and the PbS active centers in the core overlap with the bismuth luminescent centers. In addition, by doping PbS, the dispersibility of Bi₂O₃ doping is increased, which can improve the bismuth doping efficiency. At the same time, by adjusting the size of the PbS quantum dots to be 3.00-6.00 nm, the luminescent centers overlap with the bismuth active centers, which can improve the luminous efficiency in the O and E bands. When doping Bi₂O₃ and PbS nanoparticles by using the ALD technique, the deposition concentrations of various doped materials and the uniformity within the deposition range can be precisely controlled by adjusting the deposition temperature, the pulse time of the precursor, the vapor pressure, the gas flow rate, and the deposition cycle. Specifically, when doping Bi₂O₃ by using the ALD technique, Bi(tmhd)₃ is used as the precursor, and deionized water or ozone is used as the oxygen source. When doping PbS nanoparticles, Pb(tmhd)₂ is used as the precursor, and H₂S is used as the sulfur source.
Step 3: Execute Step 1 and Step 2 again to form the loose layer (2) and the active core layer (3) once more. That is, the deposition of the loose layer by MCVD and the deposition of the active core layer by ALD are cycled twice, realizing the efficient retention of the active materials Bi₂O₃ and PbS in a high-temperature environment and further increasing the doping concentration.
Step 4: Deposit a SiO₂ material doped with a small amount of GeO₂ and P₂O₅ on the doped material by using the modified chemical vapor deposition technique, and regulate the optical fiber waveguide parameters to form the inner core layer (4).

The optical fiber fabricated by the fabrication method proposed by the present disclosure exhibits multiple absorption peaks in the wavelength range of 400-1700 nm, including the absorption peaks of Bi ions near the wavelengths of 500, 700, and 800 nm, as well as an absorption envelope in the range of 1150-1450 nm. The absorption peak in the range of 1150-1450 nm includes the absorption range of the regulated PbS quantum dots. This optical fiber has a broadband gain in the O+E band under the excitation of 1180-1240 nm pumping.

In addition, the optical fiber fabricated by the fabrication method proposed by the present disclosure exhibits low-noise figure broadband fluorescence in the O+E band range. When the fiber length is 20-60 μm, for an O+E band fiber amplifier built with bismuth-doped fiber, under the pumping of 1180-1240 nm, a wide bandwidth of greater than 100 nm with a noise figure lower than 4 dB and a wide bandwidth of greater than 150 nm with a gain greater than 20 dB is achieved.

Embodiment 1 is a bismuth (Bi)-doped silica fiber based on the atomic layer deposition technique fabricated by the fabrication method proposed by the present disclosure. The doping distribution is shown in FIG. 1. In the fabrication process, the MCVD process is used to deposit the loose layer on the base tube, and the ALD technique is used to deposit Bi₂O₃ and PbS nanoparticles. The loose layer and the bismuth oxide nanoparticle active core layer are cycled twice. The structure of the fabricated optical fiber, from the outside to the inside, is successively a cladding (1), a loose layer (2), an active core layer (3), a loose layer (2), an active core layer (3), and an inner core layer (4). The loose layer (2) is formed by the fusion deposition of a SiO₂ material doped with GeO₂ and P₂O₅.

The core diameter is 8.1 μm, the cladding diameter is 125.23 μm, and the bismuth doping concentration is 0.020 mol %. The measured noise figure characteristics of the optical fiber are as follows: under the pumping of 1240 nm, based on a fiber length of 40 μm, the noise figure of the optical amplifier in the O+E band is lower than 4 dB in the bandwidths of 1300-1360 nm and 1395-1435 nm. The gain and noise figure in the O+E band is shown in FIG. 3.

Embodiment 2 is a bismuth (Bi)-doped silica fiber based on the atomic layer deposition technique fabricated by the fabrication method proposed by the present disclosure. In the fabrication process, the MCVD process is used to deposit the loose layer on the base tube, and the ALD technique is used to deposit Bi₂O₃ and PbS nanoparticles. The loose layer and the bismuth oxide nanoparticle active core layer are cycled twice. The structure of the fabricated optical fiber is shown in FIG. 2. From the outside to the inside, it is successively a cladding (1), a loose layer (2), an active core layer (3), a loose layer (2), an active core layer (3), and an inner core layer (4). The loose layer (2) is formed by the fusion deposition of a SiO₂ material doped with GeO₂ and P₂O₅.

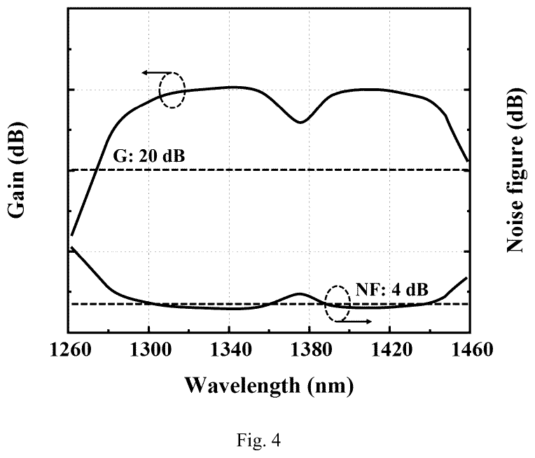

The core diameter is 8.8 μm, the cladding diameter is 125.97 μm, and the bismuth doping concentration is 0.026 mol %. The measured noise figure characteristics of the optical fiber are as follows: under the pumping of 1240 nm, based on a fiber length of 30 m, the noise figure of the optical amplifier in the O+E band is lower than 4 dB in the bandwidths of 1300-1360 nm and 1390-1430 nm. The gain and noise figure in the O+E band is shown in FIG. 4.

In the embodiments, the doping concentrations of the Bi and PbS co-doped active silica fiber are shown in the following table:

| | Bi | Pb | S | Si | O | P | Ge |
|---|---|---|---|---|---|---|---|
| | (at % ) | (at %) | (at %) | (at %) | (at %) | (at % ) | (at %) |
| Example 1 | 0.020 | 0.312 | 0.334 | 32.290 | 66.108 | 0.398 | 0.538 |
| Example 2 | 0.026 | 0.265 | 0.290 | 32.048 | 66.541 | 0.352 | 0.550 |

The present disclosure proposes a broadband low-noise figure bismuth-doped silica fiber for the O+E band and its fabrication method. Through the fabrication process of ALD+MCVD, PbS nanoparticles are co-doped in Bi₂O₃ to improve the dispersion of Bi doping. At the same time, the size of PbS particles is regulated to increase the doping concentration, and improve the luminescence efficiency in the O and E bands. In addition, in the deposition step, the core layer deposition and the loose layer deposition are alternately cycled twice, further increasing the doping concentration and luminescence efficiency, reducing the length of the bismuth-doped silica fiber required for use in an optical amplifier, reducing the influence of ASE noise during transmission, and decreasing the noise figure of the optical amplifier in the O+E band, laying a solid foundation for the application of high-performance lasers.

Only several specific embodiments of the present disclosure have been disclosed above. However, the present disclosure is not limited thereto, and any changes that can be conceived by those skilled in the art shall fall within the protection scope of the present disclosure.

1. A broadband low-noise figure bismuth-doped silica fiber for O+E band, wherein the optical fiber comprises, from the outside to the inside, in sequence: a cladding (1) and a core; the core comprises, from the outside to the inside, in sequence: a porous layer (2), an active core layer (3), a porous layer (2), an active core layer (3), and an inner core layer (4); and
wherein, the cladding (1) is made of pure silica material, the porous layer (2) and the inner core layer (4) are formed by the deposition of a SiO₂ material doped with GeO₂ and P₂O₅, and the active core layer (3) is deposited with Bi₂O₃ and PbS nanoparticles.

2. The broadband low-noise figure bismuth-doped silica fiber for O+E band according to claim 1, wherein the doping concentration of Bi ions is 0.02-0.04 mol %.

3. The broadband low-noise figure bismuth-doped silica fiber for O+E band according to claim 1, wherein the diameter of the cladding (1) is 125±2 μm, the diameter of the core is 8±1 μm, and the refractive index difference between the cladding (1) and the core is 0.004-0.010.

4. The broadband low-noise figure bismuth-doped silica fiber for O+E band according to claim 1, wherein the doping concentrations of the SiO₂ material doped with GeO₂ and P₂O₅ comprises:
the doping molar ratio of GeO₂ to SiO₂ is 0.02-0.5;
the doping molar ratio of P₂O₅ to SiO₂ is 0.04-0.8;
the doping molar ratio of GeO₂ to P₂O₅ is 0.3-1.5.

5. A method for fabricating a broadband low-noise figure bismuth-doped silica fiber for O+E band, comprising the fabrication of an optical fiber preform and the drawing of the optical fiber preform into an optical fiber;
the fabrication of the optical fiber preform comprises the following steps:
depositing the porous layer (2) and the inner core layer (4) using the modified chemical vapor deposition technique; and
depositing Bi₂O₃ and PbS nanoparticles using the atomic layer deposition technique to form the active core layer (3).

6. The fabrication method according to claim 5, wherein the specific steps of fabricating the optical fiber preform comprises:
Step 1: deposit a SiO₂ material doped with a small amount of GeO₂ and P₂O₅ on the inner wall of the silica tube using the modified chemical vapor deposition technique as a porous layer, and semi-vitrify it to form the porous layer (2);
Step 2: dope Bi₂O₃ and PbS nanoparticles using the atomic layer deposition technique to form the active core layer (3);
Step 3: perform Step 1 and Step 2 again to form the porous layer (2) and the active core layer (3) once more; and
Step 4: deposit a SiO₂ material doped with a small amount of GeO₂ and P₂O₅ on the doped material using the modified chemical vapor deposition technique to regulate the optical fiber waveguide parameters and form the inner core layer (4).

7. The fabrication method according to claim 6, wherein when doping Bi₂O₃ and PbS nanoparticles using the atomic layer deposition technique, the deposition concentration of various doping materials and the uniformity within the deposition range are precisely controlled by controlling the deposition temperature, the pulse time of the precursor, the vapor pressure, the gas flow rate, and the deposition cycle.

8. The fabrication method according to claim 7, wherein when doping Bi₂O₃ using the atomic layer deposition technique, Bi(tmhd)₃ is used as the precursor, and deionized water or ozone is used as the oxygen source; and
when doping PbS nanoparticles, Pb(tmhd)₂ is used as the precursor, and H₂S is used as the sulfur source.

9. The fabrication method according to claim 6, wherein when depositing SiO₂ using the modified chemical vapor deposition technique, the flow rate of SiCl₄ is set to 30-50 sccm; when depositing GeO₂, the flow rate of GeCl₄ is set to 20-40 sccm; when depositing P₂O₅, the flow rate of POCl₃ is set to 400-800 sccm.
